(19) United States
(12) Patent Application Publication
(10) Pub. No.: US 2025/0055498 A1
(43) Pub. Date: Feb. 13, 2025

(54) PHASED-ARRAY TRANSMITTER BASED ON INTERMEDIATE-FREQUENCY LOCAL-OSCILLATOR (IFLO) PHASE-SHIFTING ARCHITECTURE

(71) Applicant: The Hong Kong University of Science and Technology, Hong Kong (CN)

(72) Inventors: Chik Patrick YUE, Hong Kong (CN); Li WANG, Hong Kong (CN)

(21) Appl. No.: 18/795,885

(22) Filed: Aug. 6, 2024

Related U.S. Application Data
(60) Provisional application No. 63/518,882, filed on Aug. 11, 2023.

(51) Int. Cl. H04B 1/403; H04B 1/04

(52) U.S. Cl. CPC H04B 1/403; H04B 1/0483; H04B 2001/0416

(57) ABSTRACT

A phased-array transmitter system includes a plurality of signal paths and a power amplifier. Each of the signal paths comprises: a phase-shifter configured to generate a phase-shifted signal; a first mixer configured to mix the phase-shifted signal with a baseband signal to generate a first mixed signal; a variable gain amplifier (VGA) configured to perform phase-invariant gain-controlled amplification on the first mixed signal; a second mixer configured to mix the amplified first mixed signal with a radiofrequency local oscillator (RFLO) signal to generate a radiofrequency (RF) signal; and a power amplifier configured to amplify the RF signal and feed the amplified RF signal to an antenna.

### CROSS-REFERENCE TO RELATED APPLICATIONS

This patent application claims the benefit of U.S. Provisional Patent Application No. 63/518,882, filed Aug. 11, 2023, which is incorporated by reference herein in its entirety.

### BACKGROUND

A phased-array transmitter integrating multiple elements on-chip may serve as a building block for a large-scale beamforming system. Accurate phase shifting, gain control, and orthogonality between functions are considerations in ensuring beam-steering with high directivity and low sidelobe level.

A conventional radiofrequency phase-shifting (RF PS) scheme relies on I/Q vector generation and high-resolution I/Q gain control to realize phase shifting. This method is known to suffer from inferior PS linearity, PS-induced gain variation, as well as area and power overhead. Further, the adoption of RF PS and a RF variable gain amplifier (VGA) requires large power and area, and in the RF phase shifting scheme, phase-gain control is not orthogonal and there exists phase control nonlinearity.

A more recent RF local oscillator (RFLO) PS technology offers highly linear and gain-invariant PS capabilities, but at the expense of additional area and power consumption. That is, the combination of RFLO PS, additional RFLO buffer, VGA, and RFLO PS requires large power and area. Further, in the RFLO phase shifting scheme, there exists a problem of the gain control inducing phase variation, due to the usage of RF VGA.

Baseband PS technology provides improved area efficiency. However, the baseband phase shifting scheme requires complex algorithms to avoid beam squinting issues. There is also an added problem of tradeoff between PS resolution and power consumption.

### SUMMARY

In an exemplary embodiment, the present invention provides a phased-array transmitter system. The phased-array transmitter system includes a plurality of signal paths. Each of the signal paths includes: a phase-shifter configured to generate a phase-shifted signal: a first mixer configured to mix the phase-shifted signal with a baseband signal to generate a first mixed signal: a variable gain amplifier (VGA) configured to perform phase-invariant gain-controlled amplification on the first mixed signal: a second mixer configured to mix the amplified first mixed signal with a radiofrequency local oscillator (RFLO) signal to generate a radiofrequency (RF) signal; and a power amplifier configured to amplify the RF signal and feed the amplified RF signal to an antenna.

In a further exemplary embodiment, the plurality of signal paths include four signal paths, and the phase-shifter of each of the four signal paths includes an 8-2 phase multiplexer.

In a further exemplary embodiment, the phased-array transmitter system further includes: a divide-by-4 (Div-4) circuit configured to produce 8-phase intermediate frequency local oscillator (IFLO) signals.

In a further exemplary embodiment, the phase-shifter of each of the four signal paths takes as input a pair of the 8-phase IFLO signals produced by the Div-4 circuit.

In a further exemplary embodiment, the 8-phase IFLO signals are equally-spaced apart at a spacing of 45 degrees between neighboring signals.

In a further exemplary embodiment, the phased-array transmitter system further includes: an 8-phase IFLO signal distribution circuit configured to reorder the 8-phase IFLO signals for input to the phase-shifters of the plurality of signal paths.

In a further exemplary embodiment, the phase-shifter comprises a first set of switches, a set of integration-mode phase interpolators (IMPIs), and a second set of switches.

In a further exemplary embodiment, the first set of switches is configured to be controlled by a first plurality of bits to select four consecutive phases out of eight available phases: the set of IMPIs is configured to be controlled by a second plurality of bits corresponding to phase interpolation code; and the second set of switches is configured to be controlled by at least one third bit to enable phase inversion.

In a further exemplary embodiment, a respective IMPI of the set of IMPIs comprises a first branch and a second branch; and the first branch and the second branch are configured to be controlled by the phase interpolation code such that only one of the first and second branches is enabled for charging an integration capacitor.

In a further exemplary embodiment, the set of IMPIs includes four switchable segments, and the set of IMPIs is configured to alter a number of activated branches in the four switchable segments to create a linear phase shift for an integrated signal; and the phased-array transmitter system further comprises an inverter-based comparator configured to convert the integrated signal wherein the integrated signal is configured to be converted to an IMPI output signal.

In a further exemplary embodiment, the phased-array transmitter system further includes: an inductor-less RFLO buffer; and a phase-locked loop configured to provide a first RFLO signal to the Div-4 circuit and to provide a second RFLO signal to the RFLO buffer. The RFLO buffer is configured to provide the RFLO signal to the second mixer of each of the four signal paths.

In a further exemplary embodiment, the first RFLO signal and the second RFLO signal are millimeter wave RFLO signals.

In a further exemplary embodiment, the phase-locked loop comprises a passive proportional path and an active integral path.

In a further exemplary embodiment, the phase-locked loop further comprises a voltage-controlled oscillator (VCO); and the active integral path is configured to bridge an offset between a targeted frequency and a free-running frequency of the VCO.

In a further exemplary embodiment, the passive proportional path comprises loop filter capacitors.

In a further exemplary embodiment, the phase-locked loop further comprises an inductor-less true-single-phase-circuit (TSPC) Div-4 circuit and a sub-sampling (SS) buffer.

In a further exemplary embodiment, the phase-shifter of each of the four signal paths comprises a phase multiplexer and an intermedia frequency local oscillator (IFLO) phase-interpolation-based phase-shifter.

In a further exemplary embodiment, the VGA of each of the four signal paths is a transadmittance-transimpedance (TAS-TIS) VGA.

In a further exemplary embodiment, the TAS-TIS VGA comprises a Q-VGA-transadmittance stage, an I-VGA-transadmittance stage, and a transimpedance stage.

In a further exemplary embodiment, the Q-VGA-transadmittance and I-VGA-transadmittance stages are configured to convert I- and Q-IF signals into current signals; and the TAS-TIS VGA is configured to combine the current signals.

In a further exemplary embodiment, the Q-VGA-transadmittance and I-VGA-transadmittance stages comprise Gilbert-cell structures.

In another exemplary embodiment, the present invention provides a phased-array transmitter system. The phased-array transmitter system includes: a phase-shifter configured to generate a phase-shifted signal: a first mixer configured to mix the phase-shifted signal with a baseband signal to generate a first mixed signal: a variable gain amplifier (VGA) configured to perform phase-invariant gain-controlled amplification on the first mixed signal; a second mixer configured to mix the amplified first mixed signal with a radiofrequency local oscillator (RFLO) signal to generate a radiofrequency (RF) signal; and a power amplifier configured to amplify the RF signal and feed the amplified RF signal to an antenna.

In yet another exemplary embodiment, the present invention provides a method for operating a phased-array transmitter system. The method includes: producing, by a phase-locked loop, an output frequency; dividing the output frequency to produce multi-phase signals; distributing the multi-phase signals to a plurality of signal paths; and on each of the plurality of signal paths; phase-shifting a respective signal; mixing the respective signal with a baseband signal; amplifying the mixed signal; mixing the amplified mixed signal with a radiofrequency local oscillator (RFLO) signal to generate a radiofrequency (RF) signal; amplifying the RF signal; and sending the RF signal to an antenna.

### BRIEF DESCRIPTION OF THE DRAWINGS

FIGS. 1A-1D depict example embodiments of IFLO architectures according to example embodiments of the present disclosure.

FIG. 2 depicts an example of IFLO generation, distribution, and an implementation of a 7-bit IFLO phase shifter according to an example embodiment of the present disclosure.

FIG. 3 illustrates an example block diagram of an integration-mode phase interpolator (IMPI), composed of 16 equally weighted slices, according to an example embodiment of the present disclosure.

FIG. 4 depicts an example of a transadmittance-transimpedance (TAS-TIS) variable gain amplifier (VGA) according to an example embodiment of the present disclosure.

FIG. 5 illustrates an exemplary system diagram of a DP-SSPLL according to an example embodiment of the present disclosure.

FIG. 6 depicts an example circuit diagram of a true-single-phase-circuit (TSPC) divide-by-4 circuit according to an example embodiment of the present disclosure.

FIG. 7 depicts an example of an RF mixer according to an example embodiment of the present disclosure.

FIG. 8 depicts a schematic flowchart of a phased-array transmitting method according to an embodiment of this application.

### DETAILED DESCRIPTION

Example embodiments of the present disclosure include a 2×2-phased-array transmitter design utilizing intermediate-frequency local oscillator phase-shifting (IFLO PS) architecture. The IFLO PS architecture achieves highly linear and gain-invariant phase shifting, as well as phase-invariant gain control, through the integration of a phase interpolator-based IFLO phase shifter and a transadmittance-transimpedance (TAS-TIS) IF variable gain amplifier into the IF path. These example embodiments of the present disclosure may thus ensure complete orthogonality between phase shift and gain control, while also offering superior area and power efficiency compared to conventional approaches.

Various example embodiments of the disclosure now will be described more fully hereinafter with reference to the accompanying drawings, in which some, but not all embodiments of the present disclosure are shown. Indeed, embodiments of the present disclosure may be implemented in many different forms and should not be construed as limited to the example embodiments set forth herein; rather, these example embodiments are provided for the sake of illustration.

The term “or” is used herein in both the alternative and conjunctive sense, unless otherwise indicated. The terms “illustrative” and “exemplary” are used to be examples with no indication of preference. Like numbers refer to like elements throughout.

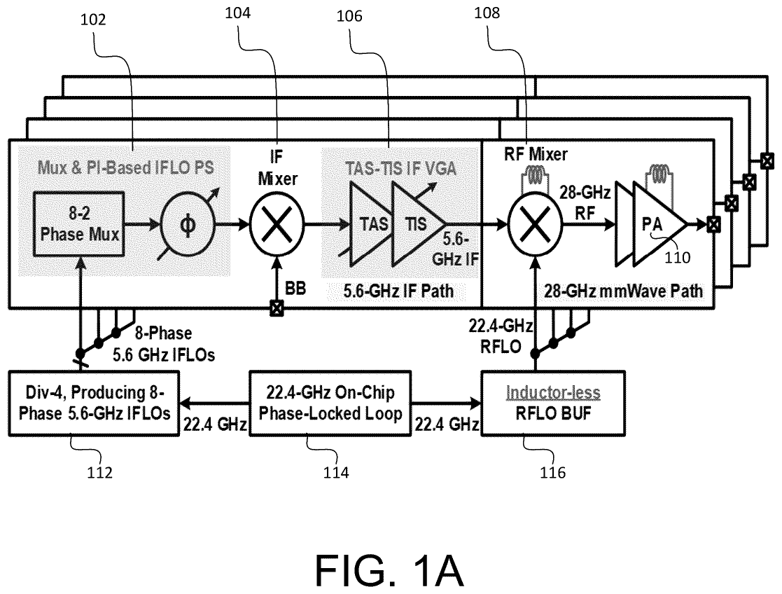

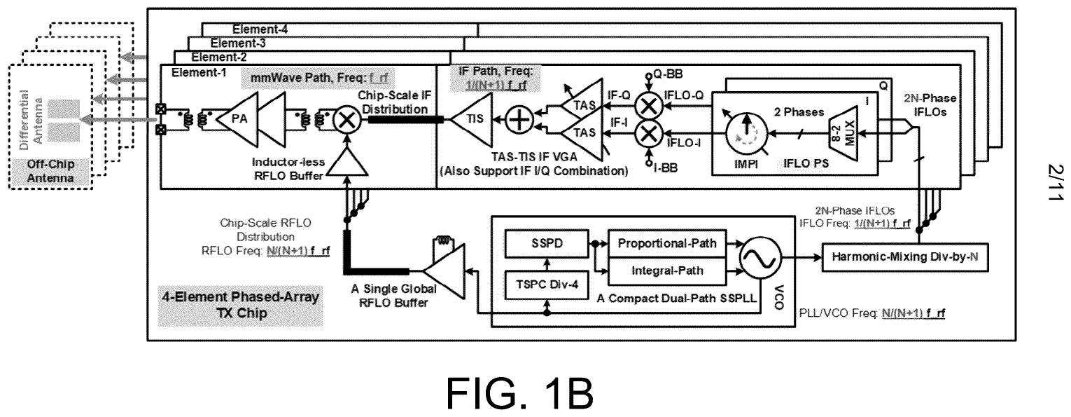

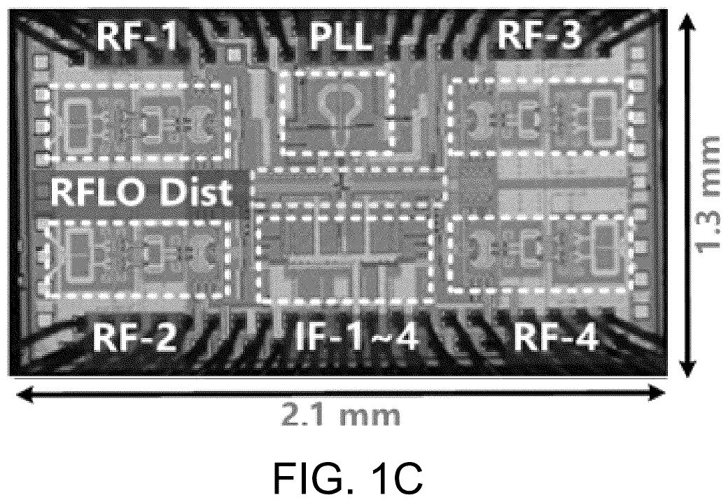

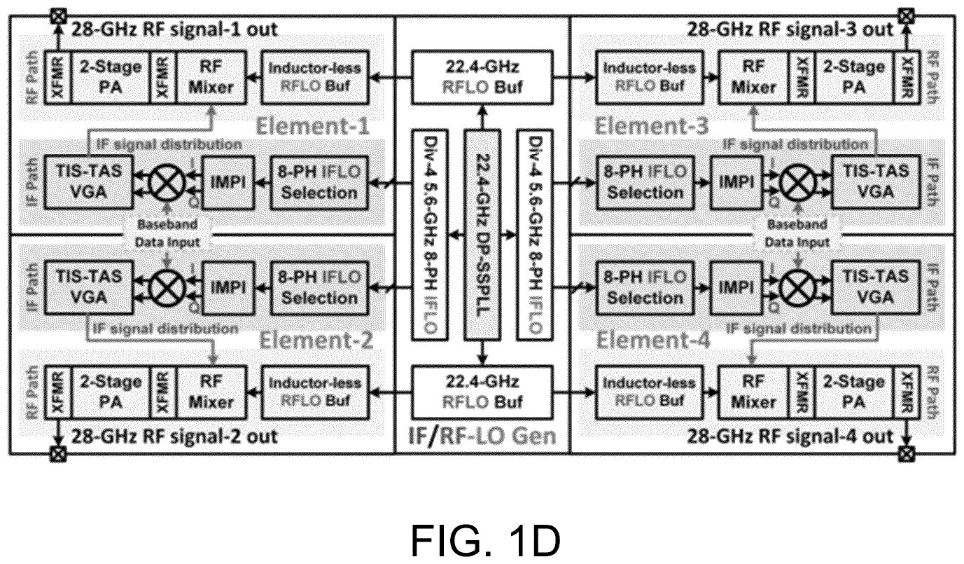

FIG. 1A shows an example embodiment of an IFLO architecture. The IFLO phase shift scheme in the depicted architecture comprises IFLO phase shifter 102, IF mixer 104, IF VGA 106, current source-less RF mixer 108, power amplifier 110, a divide-by-4 (Div-4) circuit 112, an on-chip phase-locked loop (PLL) 114, and an inductor-less RFLO buffer 116.

The IFLO phase shifting architecture adopts a sliding IF design. The local oscillator includes a mid-frequency IFLO and a millimeter-wave frequency RFLO. The RFLO is produced from the on-chip phase-locked loop 114.

For a target final output RF frequency of f_rf, the PLL frequency is set at N/(N+1)f_rf, where N can be any integer larger than 1. In an exemplary implementation, N=4 is chosen, as a divide-by-4 circuit can be designed with less complexity. The IFLO is then obtained by dividing the PLL output by N, resulting in a IFLO frequency of 1/(N+1)f_rf. During this frequency division process, 2N equally-spaced IFLO phases can be obtained, with a phase spacing of 360/(2N) degrees. The phase shifting and variable gain control functions are then implemented in the IF path for optimal accuracy, power efficiency, and area efficiency. An RF mixer 108 multiplexes the IF signal (at the frequency of 1/(N+1)f_rf) and the RFLO signal (at the frequency of N/(N+1)f_rf) to produce the desired RF signal at the frequency of f_rf.

As shown in the example of FIG. 1A, a DIV-4 circuit can be used to divide a 22.4 GHz RFLO by 4, and down to 5.6 GHZ, and this divided output serves as the IFLO. During this divide-by-4 process, eight equally-spaced phases with 45-degree spacing are produced. Next, the IFLO phase shifting function is performed using a Mux & phase interpolation (PI)-based IFLO phase shifter (PS) 102. The Mux & PI-based IFLO PS 102 may include an 8-to-2 phase mux, which selects a neighboring pair of the eight phases generated from the IFLO divider. This selection process provides coarse phase shifting with a resolution of 45 degrees. The two selected phases are then sent into the PI to perform fine phase shifting.

The phase-shifted IFLO is then mixed with a baseband signal (BB) to obtain the IF signal. The following transadmittance-transimpedance variable gain amplifier (TAS-TIS VGA) 106 provides gain-controlled amplification to the IF signal. The amplified IF signal is distributed to the RF mixer 108 and mixed with the RFLO to achieve the second-stage frequency up-conversion.

The second-stage frequency up-conversion produces the final RF signal, which is then enhanced by a power amplifier (PA) 110 and fed to an off-chip antenna. The RF signal is then radiated from the antenna into free space.

The example embodiment shown in FIG. 1A utilizes a concise mmWave path and an inductor-less RFLO buffer to provide superior power and area efficiency. Additionally, the IFLO PS provides power-efficient, highly-linear, and gain-invariant phase shifting, and the TAS-TIS IF VGA provides phase-invariant gain control.

Compared to conventional approaches, the example embodiment shown in FIG. 1A provides better power efficiency, better (smaller) area usage, better phase control accuracy, and better gain control accuracy. Additionally, the example embodiment shown in FIG. 1A provides complete orthogonality between phase and gain control (there is almost no interaction between phase shift and gain control, whereas the conventional approaches all have severe interaction or gain control affecting phase shift), good phase linearity, as well as an on-chip frequency synthesizer solution (which none of the conventional approaches provide).

FIGS. 1B-IC show another example embodiment of an IFLO architecture with respect to a prototyped chip in a 40-nm CMOS process. FIG. 1B is a block diagram of the chip, and FIG. 1C shows the area occupied by the chip.

The IFLO phase shifting-based phased-array transmitter chip, as depicted in FIG. 1B, comprises a PLL with a harmonic-mixing injection-locked frequency div-by-4 (ILFD) for global IF&RFLO generation, four IF paths, and four RF paths. A dual-path subsampling PLL architecture is chosen for the 22.4-GHz RFLO generation because of its small loop filter capacitor, which enables a compact layout that is suitable for on-chip integration.

The RFLO is efficiently distributed to the four RF paths using a single resonance-mode global buffer and four inductor-less local buffers. The RFLO is also divided by 4 using the ILFD to generate eight 45-degree-equally-spaced IFLO phases (PH-0°, 45° . . . 315°). In each of the four IF paths, an 8-to-2 phase multiplexer (mux) followed by an integration-mode phase interpolator (IMPI) forms a highly linear phase shifter.

The IFLO phase shifter performs interpolation among the eight phases from ILFD to produce the IFLO-I and Q signals, which are then mixed with the I- and Q-baseband signals using a double-balanced passive mixer to generate the IF-I and Q signals. A transadmittance-transimpedance (TAS-TIS) IF VGA first amplifies the IF-I and Q signals, then combines them, and finally distributes the combined IF signal to the RF mixer. In the RF path, the 5.6-GHz IF is upconverted to a 28-GHz RF signal. The RF signal is then amplified by a power amplifier (PA) and transmitted to the off-chip antenna.

As shown in FIG. 1C, the area occupied by the chip may be 2.1×1.3 mm² in an exemplary implementation, which is smaller than conventional architectures (e.g., some conventional architectures have the sizes of 15.8×10.5 mm². 3.2×2.3 mm². 4×3 mm². 5.2×6.6 mm². 5.2×6.6 mm²).

FIG. 1D is another depiction of the IFLO architecture of FIG. 1B. In the depiction of FIG. 1D, all four IF and RF paths of the 2×2-phased-array transmitter, as well as an IF/RF LO generation block, are illustrated.

The low-jitter RFLO cantered at 22.4 GHz is generated from a dual-path subsampling phase-locked loop (DP-SSPLL) and is then distributed to four RF paths with inductor-less buffers. Driven by the RFLO, a harmonic-mixing injection-locked frequency divider (ILFD) produces the 8-phase (8-PH) 5.6-GHz IFLO, which is delivered into the four IF paths using inverted-based buffer. In each IF path, a 7-bit phase shifter (PS) is realized by 3-bit phase selection and 4-bit integration-mode phase interpolation (IMPI). Due to the 8-PH IFLO, the IMPI achieves better accuracy than conventional I/Q phase interpolation, by utilizing X and Y input phases that are spaced 45 degrees apart from. The PS generates I and Q IFLO signals, which are subsequently mixed with the I and Q baseband input data using a pair of double-balanced passive mixers.

In contrast to conventional approaches which adopt area- and power-hungry RF VGA, a TAS-TIS VGA which supports four functions is provided in example embodiments of the present disclosure. The four functions include: (1) I and Q IF signal combination, (2) 20-dB phase-invariant gain control range. (3) 8-dB maximum gain, and (4) 7-dBm P_{O1dB} referencing to 50-Ohm. The TAS-TIS VGA is capable of driving a capacitive loading of 120-fF with over 8-GHz 3-dB bandwidth. Therefore, the VGA 110 can support chip-scale IF signal distribution to the four RF mixers 120 located in the RF path. In the RF path, a current source-less RF mixer 120 multiplexes the RFLO and IF signals to generate the RF signal, which is then amplified by a power amplifier (PA) and sent off-chip. The coupling between RF mixer 120, PA and chip pad are all implemented with a transformer (XFMR).

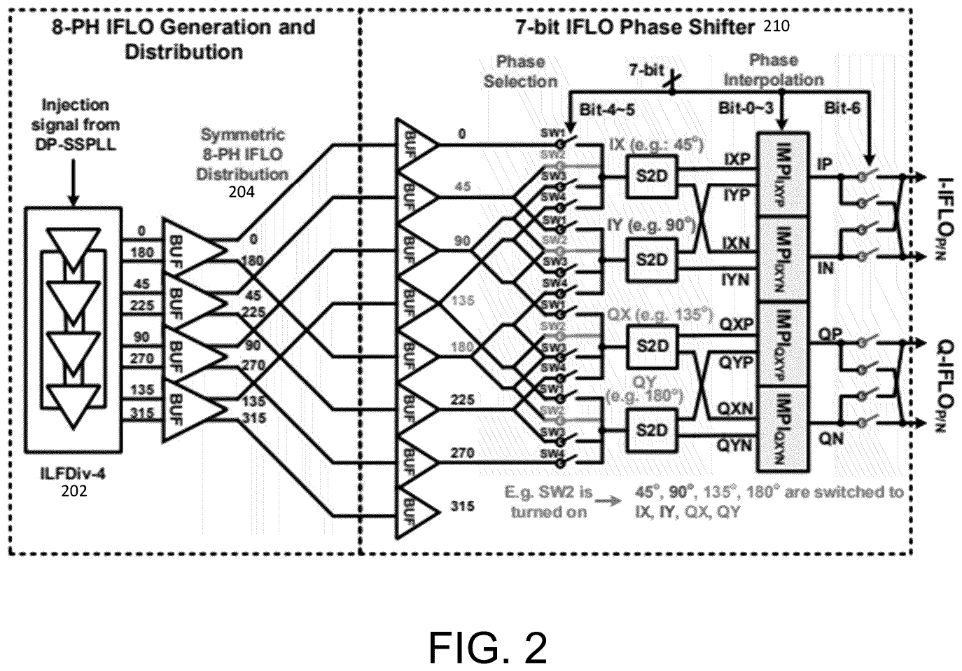

FIG. 2 depicts an example of IFLO generation, distribution, and an implementation of a 7-bit IFLO phase shifter according to an example embodiment of the present disclosure.

A ring-oscillator-based harmonic-mixing injection-locked frequency divide-by-4 circuit (ILFDiv-4) 202 produces the 8-phase IFLO (from 0°, 45°, 90°, to 315°), including 4 pairs of differential signals. Originally, these 4 pairs of differential signals were arranged in the order of 0°, 180°, 45°, 225°, 90°. 270°, 135°, 315°, which may make the subsequent phase interpolation difficult to implement. To address this, the differential signals are first rearranged into the order of 0°, 45°, 90°, 135°, 180°, 225°, 270°, 315° by the symmetric 8-PH IFLO distribution circuit 204. This new order allows the signals to be distributed symmetrically towards the IFLO phase shifter (PS) 210, facilitating the phase interpolation process.

The IFLO PS 210 has a 7-bit resolution, where the most significant bit (Bit-6) controls a cross-connected switch to enable 180-degree phase inversion. The following bits, Bit-4 to 5, control sw1˜4, to select a group of consecutive 4 phases out of the 8 available phases. To illustrate, when Bit-4:5 is set to 01, sw2 is activated, causing PH-45, PH-90, PH-135, and PH-180 to be switched to the output IX, IY, QX, and QY, respectively. The four selected phases are converted into differential signals and then sent to four integration-mode phase interpolators (IMPIs) to yield two pairs of quadrature differential IFLO signals, namely I-IFLO_{PN} and Q-IFLO_{PN}.

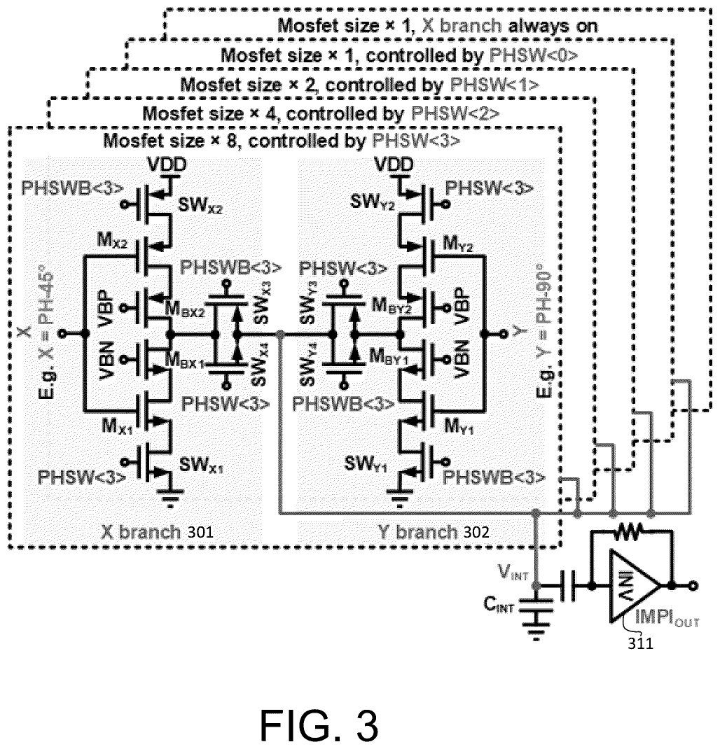

FIG. 3 illustrates an example block diagram of an IMPI, composed of 16 equally weighted slices, according to an example embodiment of the present disclosure.

The IMPI can be categorized into five segments, including one fixed segment and four binarily-ratioed switchable segments, as shown in FIG. 3. Each segment includes an X branch 301 and a Y branch 302. Controlled by phase interpolation code (Bit-0˜3), only one of the X or Y branches is enabled in each segment to charge CNT. By altering the number of activated X and Y branches in the four switchable segments, a linear phase shift can be created in the integrated signal V_{INT}. V_{INT} is converted into IMPI_{OUT} using an inverter-based comparator 311, which has a rail-to-rail swing. IMPI_{OUT} is then transformed into a differential IFLO signal to drive the next IF passive mixer.

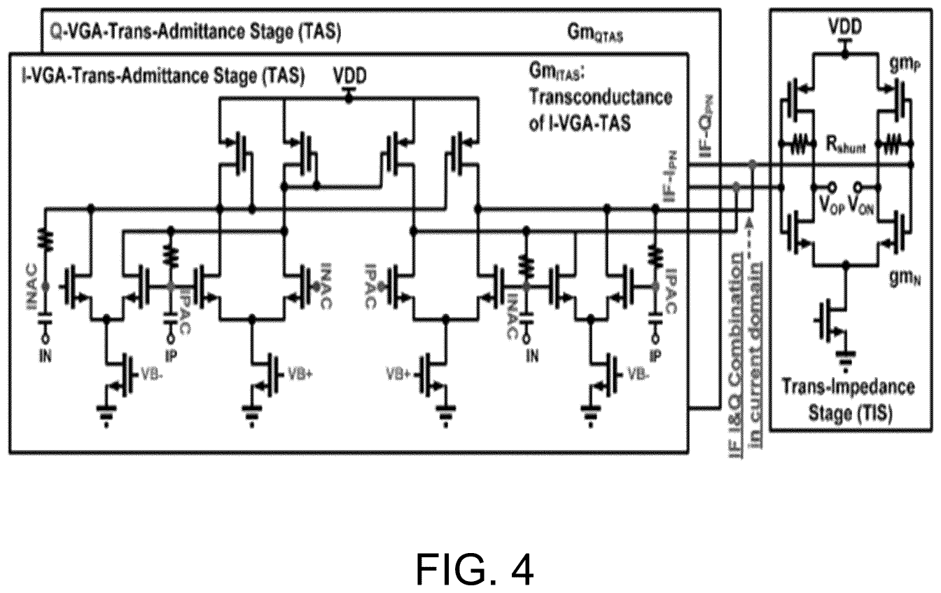

FIG. 4 depicts an example of a TAS-TIS VGA according to an example embodiment of the present disclosure.

The transadmittance-transimpedance (TAS-TIS) IF VGA is responsible for phase-invariant gain control, I/Q IF signal combination, and chip-scale IF distribution. The I and Q-IF signals from the previous stage passive mixer are converted into current signals through the first-stage TASs and are combined by directly jointing the two TAS output nodes. Gilbert-cell structures are implemented within the TASs to enable variable gain control. The second-stage TIS presents a low impedance (Rₛₕᵤₙₜ/Gain_{TIS}) to the first-stage TAS output node and enables a wide bandwidth for the node. Due to the broad bandwidth, the nonlinear parasitic capacitance variation in the Gilbert cells during a gain tuning process causes minimal phase variation, thereby leading to phase-invariant gain control. The large transimpedance of approximately 1 kΩ (Rₛₕᵤₙₜ in the TIS) contributes for a large VGA peak gain. Furthermore, the TIS exhibits a low output impedance equal to 1/(gm_{P}+gm_{N}), supporting an wide overall VGA bandwidth. In a post-layout simulation, it was shown that an exemplary implementation of the TAS-TIS IF VGA depicted in FIG. 4 achieves a 20-dB gain tuning range with a 0.38° RMS VGA-induced phase error. The wide bandwidth of the VGA also facilitates chip-scale IF signal distribution from the IF path to the RF mixer.

The illustrative TAS-TIS VGA depicted in FIG. 4 ensures several functions in the overall system, such as phase-invariant gain control, a broad range of gain tuning, adequate PO1dB, chip-scale distribution of IF signals, and combination of I/Q IF signals. Conventional approaches of using a pair of Gilbert cells for summing the I and Q signals for I/Q combination suffer from both gain-bandwidth and gain-linearity tradeoff due to the adoption of resistive loading. Therefore, it cannot support sufficient gain, PO1dB and huge capacitive loading from IF distribution. The TAS-TIS VGA of FIG. 4, on the other hand, provides all the aforementioned functionalities through three features:
First, the VGA voltage gain is determined by TAS transconductance (Gm_{ITAS} and Gm_{QTAS}) and TIS shunt impedance (Rₛₕᵤₙₜ), while the bandwidth is determined by output parasitic capacitance and TIS output impedance (gm_{P} and gm_{N}). This allows for independent optimization of both gain and bandwidth.
Second, since the I and Q IF signals are converted into current signals via the TAS, the I- and Q-VGA-TAS output nodes can be directly connected to enable current domain I&Q combination. This approach significantly improves linearity, as it is not subject to voltage headroom limitations.
Third, the Gilbert topology employed in the TAS enables variable gain control by adjusting the gate voltages of the biasing current sources (VB+ and VB−). The wide bandwidth of the VGA allows it to maintain negligible phase variation over an 18-dB gain control range. Additionally, it can facilitate IF signal distribution from the VGA 110 to RF mixer 120 and accommodate large parasitic capacitances associated with such long-distance distribution.

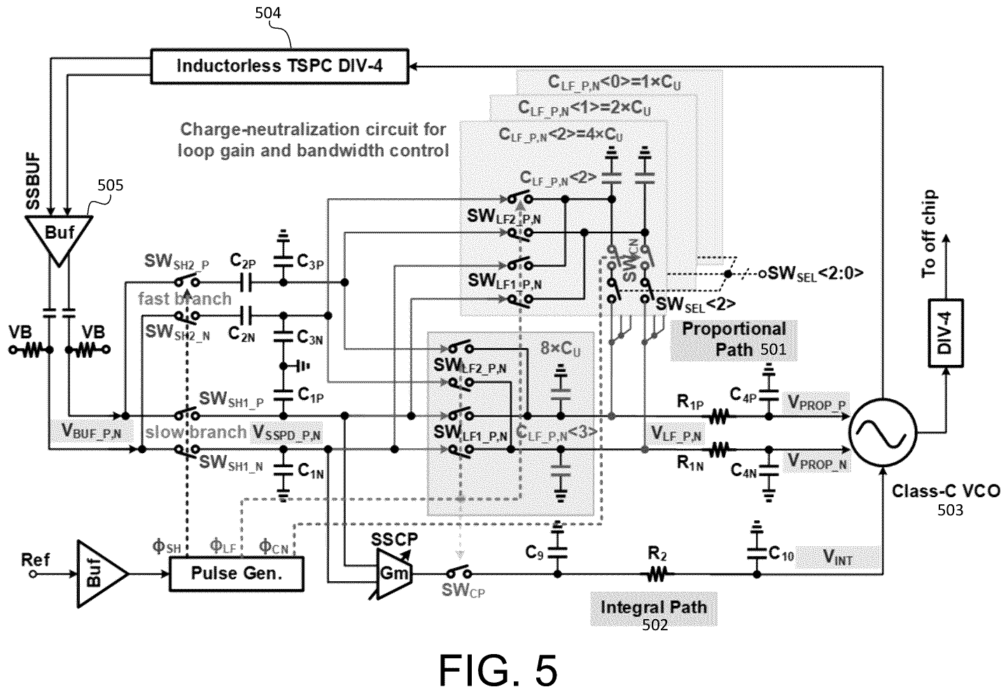

FIG. 5 illustrates an exemplary system diagram of a DP-SSPLL according to an example embodiment of the present disclosure.

The DPSSPLL architecture encompasses an all-passive proportional path 501, an active integral path 502, a class-C voltage-controlled oscillator (VCO) 503, and a true-single-phase-circuit (TSPC) divide-by-4 (DIV-4) circuit 504 with SS-buffer 505. The proportional path 501 dominates the overall loop dynamics. It serves to track the phase noise and determine the PLL bandwidth. To achieve gain and bandwidth allocation, a passive charge-domain gain control circuit enables a wide range of bandwidth adjustment with negligible phase noise contribution and power consumption. On the other hand, the integral path 502 bridges the offset between the targeted frequency and the VCO's free-running frequency. It comprises a SSCP with a small transconductance (Gm) and a C-R-C loop filter. Lowering the Gm in the integral path 502 serves two purposes: minimizing the bandwidth to prevent additional phase noise contribution, and avoiding the need for large integrating capacitors (C₉, C₁₀). For the prescaling and VCO buffering functions, an inductorless true-single phase clock-type divide-by-4 (DIV-4) circuit 504 is utilized. This TSPC divider 504 is not only power-efficient, but can also enhance the area efficiency compared to a resonance-mode buffer. Following the TSPC DIV-4 504, an SSBUF 505 is employed to drive the SSPD through an AC-coupled network. The AC-coupling serves to establish an appropriate biasing voltage, ensuring a sufficient overdrive voltage for the SSCP in the integral path 502.

The dual-path architecture depicted in the example embodiment of FIG. 5, including the differential proportional path 501 and the single-ended integral path 502, offers the following:
First, the integral path 502's high gain ensures that the voltage offset between the P and N sides of the proportional path 501 (V_{PROP_P}-V_{PROP_N}) approaches zero when reaching the locked state. Consequently, the charge stored on the loop filters C_{LFP} and C_{LFN} comprises a common DC component and a differential AC component with opposite polarities.
Second, the passive proportional path 501 alone provides a maximum loop bandwidth of approximately 8 MHz, which exceeds the optimal loop bandwidth in most cases, considering reasonable reference phase noise and VCO power consumption. To optimize the bandwidth and strike a balance between in-band and out-of-band PN, controllable charge neutralization can be employed to partially neutralize the AC charge stored on the P and N-side loop filter capacitors C_{LFP} and C_{LFN}. Since the DC voltages of V_{PROP_P} and V_{PROP_N} are identical, this charge neutralization only affects the AC signal, allowing for gain adjustment without causing mislocking.

To achieve controllable charge neutralization, a 4-bit capacitor bank is used for the loop filter capacitors on the proportional path 501. The capacitance values range from 8×C_{U}, 4×C_{U}, 2×C_{U} to 1×C_{U}, with the most significant bit (MSB), C_{LFP,N}<3>, fixed to the P, N side. The remaining three bits, C_{LFP,N}<2:0>, can be redistributed using SWCN to steer the charge to the opposite sides. The involvement of capacitance (charge) in the neutralization process is controlled by 3-bit switches, SW_{SEL}<2:0>. Ensuring reasonable capacitance matching in the 4-bit capacitor bank requires a sufficiently large total loop filter value. However, conventional switched-capacitor type-I configurations cannot meet this requirement due to the stringent phase margin. To overcome this, a dual-branch SSPD is utilized to accommodate a large loop filter capacitance without compromising the phase margin

In other words, the DP-SSPLL of FIG. 5 includes a passive proportional path (P-path) and an active integration path (I-path). While a conventional passive PLL loop has low phase noise, it can suffer from a phase margin-bandwidth tradeoff and is unable to achieve loop gain tuning. To address these limitations, the P-path introduces an in-band zero by adopting sample-and-hold switches (SW_{SH3,4}), loop filter switches (SW_{LF3,4}), and sampling capacitors C_{3˜5}. This design ensures sufficient phase margin even under large loop bandwidths. Additionally, the loop filter capacitor C₁₀ is comprised of three slices with capacitance ratios of 4:2:1. By controlling the charge sharing switch (SW_{CS}), the sampled charge on C₉ and C₁₀ can be shared with the opposite side loop filter capacitors (C₈ and C₇), allowing for adjustable gain of the P-path. The I-path is responsible for enhancing the SS-phase detector gain and attenuating close-in flicker noise of the voltage-controlled oscillator.

In the feedback path, an inductor-less true-single-phase-circuit (TSPC) divider is adopted to achieve power- and area-efficient frequency division.

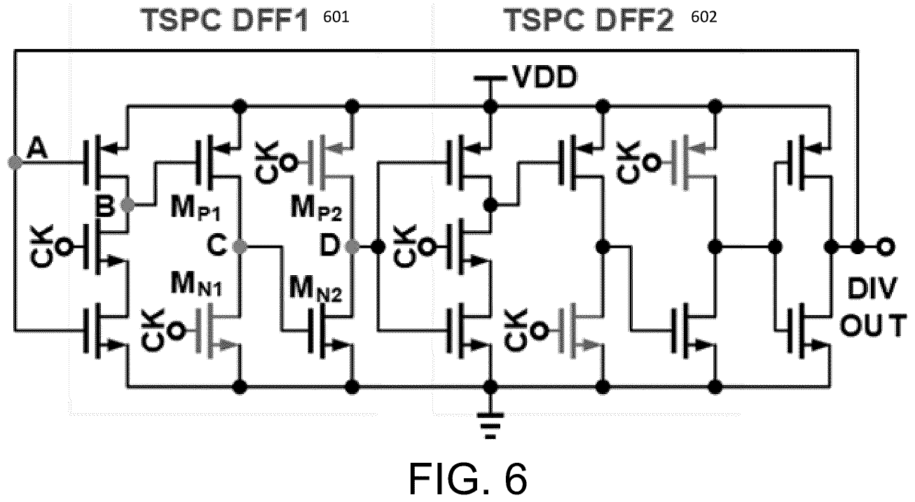

FIG. 6 depicts an example circuit diagram of a TSPC divide-by-4 circuit according to an example embodiment of the present disclosure.

The TSPC DIV-4 circuit includes two ratioed TSPC DFFs and an inverter. TSPC DFF1 601 takes the input signal from node A and produces an inverted output signal at node D during every falling edge of CK. TSPC DFF2 602, along with the inverter, forms a latch that retains the signal level on node D for one input clock cycle. As a result, a complete output cycle on DIV OUT requires four input clock cycles, achieving a divide-by-4 operation. The input clock is directly sourced from the VCO.

In an exemplary implementation, the TSPC divider is composed of two TSPC D flip-flops and an inverter, and is capable of operating at speeds up to 27 GHZ under the slow-slow corner while consuming only 1.4 mW of power.

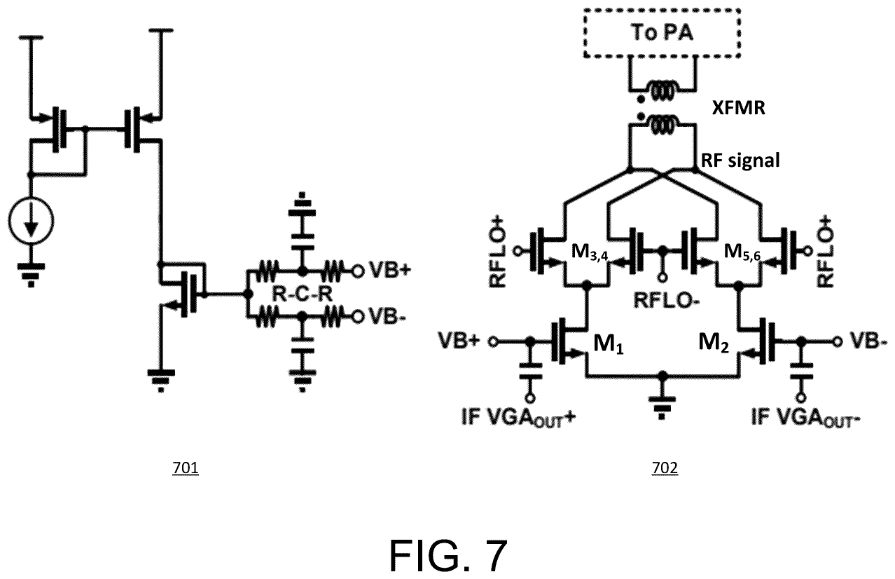

FIG. 7 depicts an example of an RF mixer according to an example embodiment of the present disclosure.

The RF mixer circuit includes a biasing circuit 701 (left side of FIG. 7) and a Gilbert mixer core 702 (right side of FIG. 7). The input MOSFETs of the Gilbert mixer core 702, M1 and M2, serve two purposes. First, they accept the input IF signal. Second, they control the biasing current of the Gilbert mixer core circuit 702. The IF signal (IF VGA_{OUT+/-}) from the previous IF VGA stage is fed into M1 and M2 through an AC coupling capacitor. The biasing voltage level is generated by the biasing circuit and then passed through an R-C-R network into M1 and M2. The RFLO+/− signal has a rail-to-rail swing, which can fully saturate the switching MOSFETs M3/4 and M5/6. This allows the RFLO signal to upconvert the IF signal to the desired RF frequency. Second, the output RF signal is coupled through a transformer (XFMR) to the next stage power amplifier (PA). The XFMR also has the added benefit of resonating with the mixer output parasitic capacitance to enhance the power gain.

In other words, since there is no RF VGA between the RF mixer and the PA, the RF mixer should achieve sufficient gain and a wide PO1dB. To address this, the RF mixer does not utilize a current source and instead utilizes an IF input MOSFET as a pair of current mirrors with an R-C-R biasing network. This improves the dynamic range of the mixer output by approximately 0.2 V. To further increase the PO1dB, a transformer (XFMR) is employed to match the PA input with the mixer output impedance. The XFMR also has the added benefit of resonating with the mixer output parasitic capacitance to enhance the power gain.

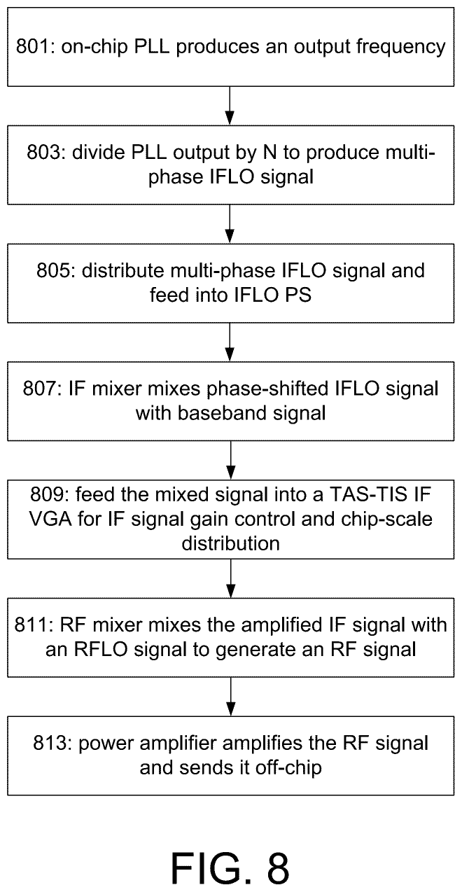

FIG. 8 depicts a flowchart of a phased-array transmitting method according to an example embodiment of the present disclosure.

At stage 801, assuming a target RF frequency is f_rf, an on-chip PLL produces an output frequency at N/(N+1)f_rf, where N can be any integer larger than 1. In an exemplary implementation, the value for N is 4.

At stage 803, the PLL output is divided by N to produce the multi-phase IFLO signal at the frequency of 1/(N+1)f_rf. In the N=4 example, a group of 8 IFLO phases can be obtained.

At stage 805, the IFLO signal is distributed and fed the signal is fed into an IFLO PS for phase-shifting. In an exemplary implementation, the 8-PH IFLO signal is distributed and fed into a following 7-bit IFLO PS.

At stage 807, an IF mixer mixes a phase-shifted IFLO signal with a baseband signal (BB).

At stage 809, the signal goes into a TAS-TIS IF VGA for IF signal gain control and chip-scale distribution.

At stage 811, a current source-less RF mixer mixes the amplified IF signal with an RFLO signal to generate an RF signal (at f_rf).

At stage 813, a power amplifier amplifies the RF signal and sends it off-chip.

All references, including publications, patent applications, and patents, cited herein are hereby incorporated by reference to the same extent as if each reference were individually and specifically indicated to be incorporated by reference and were set forth in its entirety herein.

The use of the terms “a” and “an” and “the” and “at least one” and similar referents in the context of describing the invention (especially in the context of the following claims) are to be construed to cover both the singular and the plural, unless otherwise indicated herein or clearly contradicted by context. The use of the term “at least one” followed by a list of one or more items (for example, “at least one of A and B”) is to be construed to mean one item selected from the listed items (A or B) or any combination of two or more of the listed items (A and B), unless otherwise indicated herein or clearly contradicted by context. The terms “comprising,” “having.” “including,” and “containing” are to be construed as open-ended terms (i.e., meaning “including, but not limited to,”) unless otherwise noted. Recitation of ranges of values herein are merely intended to serve as a shorthand method of referring individually to each separate value falling within the range, unless otherwise indicated herein, and each separate value is incorporated into the specification as if it were individually recited herein. All methods described herein can be performed in any suitable order unless otherwise indicated herein or otherwise clearly contradicted by context. The use of any and all examples, or exemplary language (e.g., “such as”) provided herein, is intended merely to better illuminate the invention and does not pose a limitation on the scope of the invention unless otherwise claimed. No language in the specification should be construed as indicating any non-claimed element as essential to the practice of the invention.

Preferred embodiments of this invention are described herein, including the best mode known to the inventors for carrying out the invention. Variations of those preferred embodiments may become apparent to those of ordinary skill in the art upon reading the foregoing description. The inventors expect skilled artisans to employ such variations as appropriate, and the inventors intend for the invention to be practiced otherwise than as specifically described herein. Accordingly, this invention includes all modifications and equivalents of the subject matter recited in the claims appended hereto as permitted by applicable law. Moreover, any combination of the above-described elements in all possible variations thereof is encompassed by the invention unless otherwise indicated herein or otherwise clearly contradicted by context.

1. A phased-array transmitter system, comprising:
a plurality of signal paths, wherein each of the signal paths comprises:
a phase-shifter configured to generate a phase-shifted signal;
a first mixer configured to mix the phase-shifted signal with a baseband signal to generate a first mixed signal;
a variable gain amplifier (VGA) configured to perform phase-invariant gain-controlled amplification on the first mixed signal;
a second mixer configured to mix the amplified first mixed signal with a radiofrequency local oscillator (RFLO) signal to generate a radiofrequency (RF) signal; and
a power amplifier configured to amplify the RF signal and feed the amplified RF signal to an antenna.

2. The phased-array transmitter system according to claim 1, wherein the plurality of signal paths include four signal paths, and wherein the phase-shifter of each of the four signal paths includes an 8-2 phase multiplexer.

3. The phased-array transmitter system according to claim 1, further comprising:
a divide-by-4 (Div-4) circuit configured to produce 8-phase intermediate frequency local oscillator (IFLO) signals.

4. The phased-array transmitter system according to claim 3, wherein the phase-shifter of each of the four signal paths takes as input a pair of the 8-phase IFLO signals produced by the Div-4 circuit.

5. The phased-array transmitter system according to claim 4, wherein the 8-phase IFLO signals are equally-spaced apart at a spacing of 45 degrees between neighboring signals.

6. The phased-array transmitter system according to claim 5, further comprising:
an 8-phase IFLO signal distribution circuit configured to reorder the 8-phase IFLO signals for input to the phase-shifters of the plurality of signal paths.

7. The phased-array transmitter system according to claim 6, wherein the phase-shifter comprises a first set of switches, a set of integration-mode phase interpolators (IMPIs), and a second set of switches.

8. The phased-array transmitter system according to claim 7, wherein the first set of switches is configured to be controlled by a first plurality of bits to select four consecutive phases out of eight available phases:
wherein the set of IMPIs is configured to be controlled by a second plurality of bits corresponding to phase interpolation code; and
wherein the second set of switches is configured to be controlled by at least one third bit to enable phase inversion.

9. The phased-array transmitter system according to claim 8, wherein a respective IMPI of the set of IMPIs comprises a first branch and a second branch;
wherein the first branch and the second branch are configured to be controlled by the phase interpolation code such that only one of the first and second branches is enabled for charging an integration capacitor.

10. The phased-array transmitter system according to claim 9, wherein the set of IMPIs includes four switchable segments, and wherein the set of IMPIs is configured to alter a number of activated branches in the four switchable segments to create a linear phase shift for an integrated signal; and
wherein the phased-array transmitter system further comprises an inverter-based comparator configured to convert the integrated signal wherein the integrated signal is configured to be converted to an IMPI output signal.

11. The phased-array transmitter system according to claim 3, further comprising:
an inductor-less RFLO buffer; and
a phase-locked loop configured to provide a first RFLO signal to the Div-4 circuit and to provide a second RFLO signal to the RFLO buffer;
wherein the RFLO buffer is configured to provide the RFLO signal to the second mixer of each of the four signal paths.

12. The phased-array transmitter system according to claim 11, wherein the first RFLO signal and the second RFLO signal are millimeter wave RFLO signals.

13. The phased-array transmitter system according to claim 11, wherein the phase-locked loop comprises a passive proportional path and an active integral path.

14. The phased-array transmitter system according to claim 13, wherein the phase-locked loop further comprises a voltage-controlled oscillator (VCO); and
wherein the active integral path is configured to bridge an offset between a targeted frequency and a free-running frequency of the VCO.

15. The phased-array transmitter system according to claim 11, wherein the passive proportional path comprises loop filter capacitors.

16. The phased-array transmitter system according to claim 11, wherein the phase-locked loop further comprises an inductor-less true-single-phase-circuit (TSPC) Div-4 circuit and a sub-sampling (SS) buffer.

17. The phased-array transmitter system according to claim 1, wherein the phase-shifter of each of the four signal paths comprises a phase multiplexer and an intermedia frequency local oscillator (IFLO) phase-interpolation-based phase-shifter.

18. The phased-array transmitter system according to claim 1, wherein the VGA of each of the four signal paths is a transadmittance-transimpedance (TAS-TIS) VGA.

19. The phased-array transmitter system according to claim 18, wherein the TAS-TIS VGA comprises a Q-VGA-transadmittance stage, an I-VGA-transadmittance stage, and a transimpedance stage.

20. The phased-array transmitter system according to claim 19, wherein the Q-VGA-transadmittance and I-VGA-transadmittance stages are configured to convert I- and Q-IF signals into current signals; and
wherein the TAS-TIS VGA is configured to combine the current signals.

21. The phased-array transmitter system according to claim 19, wherein the Q-VGA-transadmittance and I-VGA-transadmittance stages comprise Gilbert-cell structures.

22. A phased-array transmitter system, comprising:
a phase-shifter configured to generate a phase-shifted signal;
a first mixer configured to mix the phase-shifted signal with a baseband signal to generate a first mixed signal;
a variable gain amplifier (VGA) configured to perform phase-invariant gain-controlled amplification on the first mixed signal;
a second mixer configured to mix the amplified first mixed signal with a radiofrequency local oscillator (RFLO) signal to generate a radiofrequency (RF) signal; and
a power amplifier configured to amplify the RF signal and feed the amplified RF signal to an antenna.

23. A method for operating a phased-array transmitter system, comprising:
producing, by a phase-locked loop, an output frequency;
dividing the output frequency to produce multi-phase signals;
distributing the multi-phase signals to a plurality of signal paths; and
on each of the plurality of signal paths:
phase-shifting a respective signal;
mixing the respective signal with a baseband signal;
amplifying the mixed signal;
mixing the amplified mixed signal with a radiofrequency local oscillator (RFLO) signal to generate a radiofrequency (RF) signal;
amplifying the RF signal; and
sending the RF signal to an antenna.
